(19) United States
(12) Patent Application Publication
(10) Pub. No.: US 2019/0254178 A1
(43) Pub. Date: Aug. 15, 2019

(54) DISPLAY DEVICE AND MANUFACTURING METHOD THEREOF

(71) Applicant: Innolux Corporation, Miao-Li County (TW)

(72) Inventors: Chien-Wei CHEN, Miao-Li County (TW); Tung-Chin WU, Miao-Li County (TW); Ting-Hsuan LIN, Miao-Li County (TW); Chih-Chiao YANG, Miao-Li County (TW)

(21) Appl. No.: 16/252,924

(22) Filed: Jan. 21, 2019

(30) Foreign Application Priority Data
Feb. 14, 2018 (CN) 201810151574.7

(51) Int. Cl. H05K 5/00

(52) U.S. Cl. CPC H05K 5/0017; G02F 1/133308

(57) ABSTRACT

A display device and a manufacturing method thereof are provided. The manufacturing method of the display device includes following steps: assembling a protection substrate and a display panel, wherein the protection substrate has an inner surface, facing a first surface of the display panel, and an end portion extends towards the display panel; assembling a device component and the display panel disposed between the device component and the protection substrate, wherein the device component has a component side surface, the display panel has a side surface, and a gap is formed among the end portion, the component side surface and the side surface; extending a dispensing extending portion to the gap; and dispensing an adhesive to the side surface and the component side surface to form an adhesive layer.

This application claims the benefit of People's Republic of China application Serial No. 201810151574.7, filed Feb. 14, 2018, the subject matter of which is incorporated herein by reference.

### BACKGROUND

### Technical Field

The disclosure relates in general to a display device and a manufacturing method thereof, and more particularly to a display device whose device component and display panel have an adhesive layer adhered on the side surface and a manufacturing method thereof.

### Description of the Related Art

In recent years, as the LCD module (LCM) is directed towards automated production or the narrow border or borderless design of display monitor, and the demand for curved displays, bending displays or displays with an irregular appearance increases. Therefore, the assembly or bonding between the components and the films of an LCM, also faces many challenges. The conventional technology using bonding tapes or glues gradually fail to satisfy product requirements. Therefore, it has become a prominent task for the industries to complete the said assembly or bonding of LCM without increasing the manufacturing time, assembly complexity or material cost.

### SUMMARY

The present disclosure relates to a display device and a manufacturing method thereof.

According to one embodiment of the present disclosure, a manufacturing method of a display device is provided. The manufacturing method of the display device comprises following steps: assembling a protection substrate and a display panel, wherein the protection substrate has an inner surface, facing a first surface of the display panel, an area of the inner surface of the protection substrate is larger than an area of the first surface of the display panel, and an end portion extending towards the display panel; assembling a device component and the display panel disposed between the device component and the protection substrate, wherein the device component has a component side surface, the display panel has a side surface, and a gap is formed among the end portion, the component side surface of the device component and the side surface of the display panel; extending a dispensing extending portion to the gap; and dispensing an adhesive to the side surface of the device component and the component side surface of the device component to form an adhesive layer.

According to another embodiment of the present disclosure, a display device comprising a display panel, a protection substrate, a device component and an adhesive layer is provided. The display panel has a first surface, a second surface and a side surface. The first surface corresponds to the second surface. The side surface connects the first surface and the second surface. The protection substrate is disposed opposite to the display panel. The protection substrate has an inner surface, adjacent to the first surface of the display panel, an area of the inner surface of the protection substrate is larger than an area of the first surface of the display panel, and an end portion extends towards the display panel. The device component is disposed adjacent to the second surface of the display panel. The device component has a component side surface. The adhesive layer is disposed on the side surface of the display panel and the component side surface of the device component.

The above and other aspects of the disclosure will become better understood with regard to the following detailed description of the embodiment but non-limiting embodiment(s). The following description is made with reference to the accompanying drawings.

### BRIEF DESCRIPTION OF THE DRAWINGS

FIG. 1 is a flowchart of a manufacturing method of a display device according to an embodiment of the present disclosure.

FIG. 2 is a side view of an alignment step according to an embodiment of the present disclosure.

FIG. 3 is a three-dimensional view of an alignment step according to an embodiment of the present disclosure.

FIG. 4 is a top view of an adhesive dispensing path according to an embodiment of the present disclosure.

FIG. 5 is a three-dimensional structural view of a dispensing device according to an embodiment of the present disclosure.

FIG. 6 is a side view of a dispensing device according to an embodiment of the present disclosure.

FIG. 7A to FIG. 7B are front views of a dispensing extending portion according to some embodiments of the present disclosure.

FIG. 7C is a three-dimensional view of a dispensing extending portion according to an embodiment of the present disclosure.

FIG. 7D to FIG. 7F are longitudinal sectional views of a dispensing extending portion according to some embodiments of the present disclosure.

FIG. 8A to FIG. 8C are structural views of a side surface of a partial region of a display device according to some embodiments of the present disclosure.

FIG. 8D to FIG. 8E are structural views of a side surface of a display device according to some embodiments of the present disclosure.

### DETAILED DESCRIPTION

A number of embodiments of the present disclosure are disclosed below with reference to accompanying drawings. Designations common to the accompanying drawings and embodiments are used to indicate identical or similar elements. It should be noted that the structure and content disclosed in the embodiments are for exemplary and explanatory purposes, not for limiting the scope of protection of the present disclosure. Anyone skilled in the technology field of the disclosure will be able to make suitable modifications or changes to the structures or steps to meet the needs of actual implementation. In addition, in this specification, expressions such as “first material layer disposed above/on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer. In addition, in this specification, relative expressions such as “assembling a device component and a display panel”, may indicate the aligning and combining the device component and the display panel. In addition, in this specification, relative expressions are used. For example, “bottom” or “top” is used to describe the position of one element relative to another. It should be appreciated that if a device is flipped upside down, an element that is “bottom” will become an element that is “top”. It should be understood that this description of the exemplary embodiments is intended to be read in connection with the accompanying drawings, which are to be considered part of the entire written description.

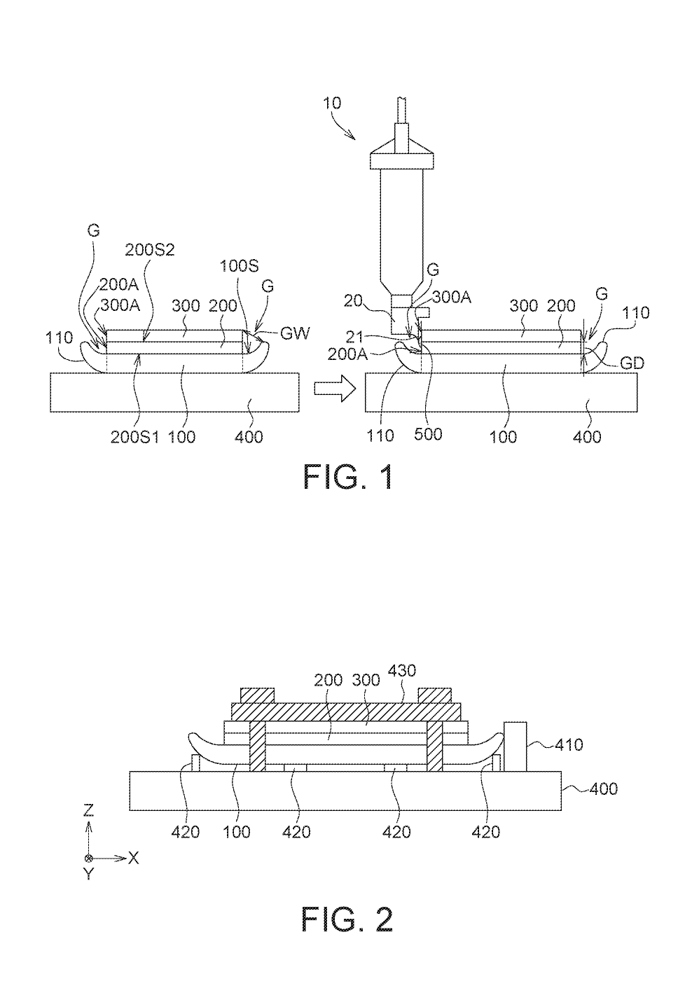

FIG. 1 is a flowchart of a manufacturing method of a display device according to an embodiment of the present disclosure. As indicated in FIG. 1, the protection substrate 100 and the display panel 200 are assembled. In some embodiments, the display panel 200 and the protection substrate 100 can be adhered through an adhesive layer (not illustrated), such as an optical clear adhesive layer (OCA) or an optical clear resin (OCR), but the present disclosure is not limited thereto. The protection substrate 100 can be realized by a substrate or an element formed of a material having protection or packaging characteristics. In an embodiment, the protection substrate 100 can be realized by a substrate formed of cover glass or other suitable material, but the present disclosure is not limited thereto.

As indicated in FIG. 1, the protection substrate 100 and the display panel 200 are assembled, the protection substrate 100 has an inner surface 100S, facing a first surface 200S1 and the area of the inner surface 100S of the protection substrate 100 larger than the area of the first surface 200S1 of the display panel 200, and an end portion 110 extending towards the display panel 200. The said arrangement that the area of the inner surface 100S of the protection substrate 100 is larger than the area of the first surface 200S1 of the display panel 200 can be that the area of the inner surface 100S is smaller than the area of the first surface 200S1. In some embodiments, the end portion 110 of the protection substrate 100 can bend (inwards or outwards) or deflect towards the display panel 200, but the present disclosure is not limited thereto. An end portion 110 of the protection substrate 100 can be defined as the non-overlapping part between the protection substrate 100 and the display panel 200 in the normal direction of the first surface 200S1.

A device component 300 and the display panel 200 are assembled. The display panel 200 is disposed between the device component 300 and the protection substrate 100. The device component 300 has a component side surface 300A. The display panel 200 has a side surface 200A. A gap G is formed among the end portion 110, the component side surface 300A and the side surface 200A. In some embodiments, the gap G can have a rectangular shape, an arced shape, a sharp-angled shape, a groove of any shape, or a combination thereof, but the present disclosure is not limited thereto. That is, the gap G can have different widths or depths with reference to the component side surface 300A or the side surface 200A. Detailed descriptions of the width or depth of the gap are disclosed below in the specification.

In an embodiment, the display device may comprise liquid crystal (LC), organic light-emitting diode (OLED), quantum dot (QD), fluorescence material, phosphor material, light-emitting diode (LED), micro light-emitting diode, micro LED, mini LED or other display medium, but the present disclosure is not limited thereto. In some embodiments, the LED chip has a size between 300 micrometers (μm) and 10 millimeters (mm), the mini LED chip has a size ranged from 100 μm to 300 μm, and the micro LED chip has a size ranged from 1 μm to 100 μm, but the present disclosure is not limited thereto.

In some embodiments, when the display panel 200 is realized by an LCD panel, the device component 300 can be realized by a backlight module. The backlight module may comprise a backlight source, an optical film (such as a light guide plate, a reflector or a diffuser, but the present disclosure is not limited thereto), and a backlight casing element (such as a back plate or a frame element, but the present disclosure is not limited thereto), and detailed descriptions are not repeated here. In the present embodiment, the device component 300 can also be realized by other components of the display device, such as another display panel used in regional dimming, but the present disclosure is not limited thereto.

In some embodiments, when the display panel 200 is realized by an LED display panel, the device component 300 comprises a circuit board or other components of the display device, but the present disclosure is not limited thereto.

In some embodiments, when the device component 300 is formed of multiple device elements, the component side surface 300A can have a bumpy surface, an arced surface or a surface of any shapes, but the present disclosure is not limited thereto. Similarly, in some embodiments, when the first substrate (not illustrated, can be realized by a array substrate) and the second substrate (not illustrated, can be realized by a color filter substrate) of the display panel 200 have different sizes and have different projection areas on the first surface 200S1, the side surface 200A can have a bumpy surface, an arced surface or a surface of any shapes, but the present disclosure is not limited thereto.

In some embodiments, other element or film (such as polarizer) can be disposed between the display panel 200 and the device component 300, but the present disclosure is not limited thereto. Other element (such as adhesive layer), film, or touch panel can be disposed between the protection substrate 100 and the display panel 200, but the present disclosure is not limited thereto.

In some embodiments as indicated in FIG. 1, after the protection substrate 100 and the display panel 200 are assembled, the protection substrate 100 and the display panel 200 are placed on a platform 400. Meanwhile, the protection substrate 100 can be disposed between the display panel 200 and the platform 400. Then, an alignment step is performed to the protection substrate 100 and the platform 400. In some embodiments, the alignment step may comprise an additional alignment step of assembling the device component 300 and the display panel 200, but the present disclosure is not limited thereto.

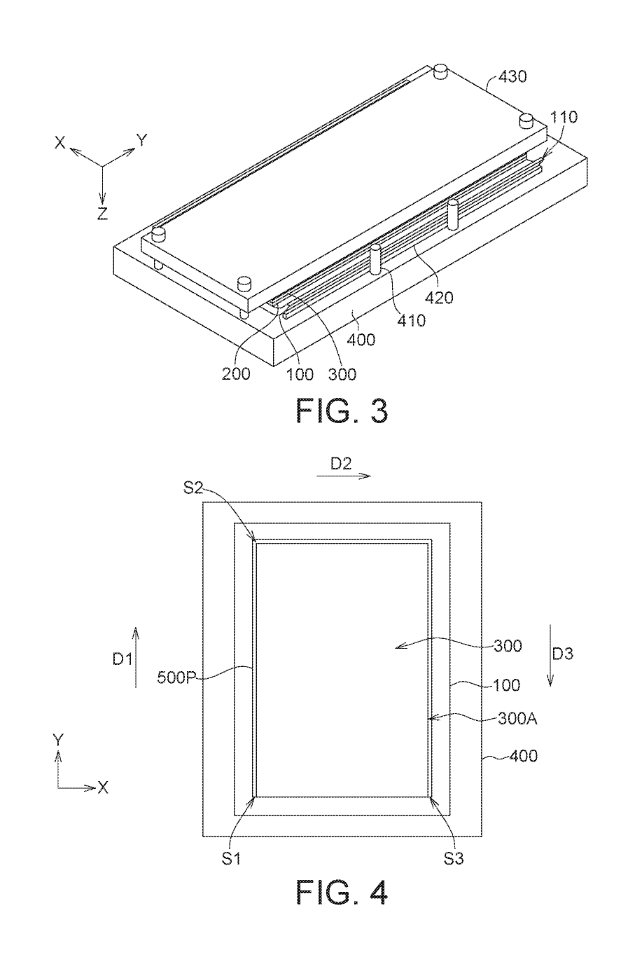

FIG. 2 is a side view of an alignment step according to an embodiment of the present disclosure. FIG. 3 is a three-dimensional view of an alignment step according to an embodiment of the present disclosure. For elements of the present embodiment similar or identical to that of above embodiments, similar or identical designations are used. Relevant descriptions of similar or identical elements which can be obtained with reference to above disclosure are not repeated here.

In some embodiments as indicated in FIG. 2 to FIG. 3, the alignment step can be performed by way of positioning mechanism elements. For example, a positioning column 410 or a positioning column 420 can be disposed on the platform 400, so that the protection substrate 100 and the display panel 200 having been assembled can be placed according to the position or height of the positioning column 410 or 420. Through the disposition of the positioning column 410 or 420, the movement or slide of the protection substrate 100 and the display panel 200 on the platform can be reduced. For example, the positioning column 410 can provide the X directional positioning to reduce the X directional displacements of the protection substrate 100 and the display panel 200. Similarly, a positioning column (not illustrated) can provide the Y directional positioning to reduce the Y directional displacements of the protection substrate 100 and the display panel 200. The positioning column 420 can provide support or positioning to the bottom to reduce the Z directional displacements of the protection substrate 100 and the display panel 200. In some embodiments, a fixing tool 430 can be disposed on the protection substrate 100, the display panel 200 and the device component 300 having been assembled together. The fixing tool 430 may comprise a main board or a fastener, but the present disclosure is not limited thereto. Through the disposition of the fixing tool 430 or the positioning column 420, the Z directional alignment and positioning of combined element structures (such as the protection substrate 100, the display panel 200 and the device component 300 having been assembled together in the present embodiment) can be enhanced. In the alignment step of some embodiments, the protection substrate 100 and the display panel 200 can be fixed on the platform using a vacuum method, but the present disclosure is not limited thereto.

In some embodiments, (not illustrated FIG. 1), the placement position of the protection substrate 100, the display panel 200 or the device component 300 having been assembled together can be detected by an image detector (such as a camera or a charge coupled device (CCD)) using optical alignment to make sure whether the protection substrate 100, the display panel 200 or the device component 300 is placed at a suitable position on the platform, but the present disclosure is not limited thereto. After the alignment step is completed, the platform can be moved to the adhering coating position. Then, the adhesive coating step is performed.

In some embodiments, following the alignment step, the image detector can perform a three-dimensional scan on the assembled elements of the display device module (comprising such as the protection substrate 100, the display panel 200 or the device component 300). For example, the image detector (such as a camera or a charge coupled device (CCD)) can perform an optical image scan on the assembled elements of the display device module using a computation control unit (not illustrated), and create a three-dimensional structural view of the entire display device module according to the feedback received from optical image scan. Then, the parameters of the adhesive dispensing or coating path can be set according to the three-dimensional structural view to achieve automatic adhesive coating, but the present disclosure is not limited thereto.

FIG. 4 is a top view of an adhesive dispensing path according to an embodiment of the present disclosure. For elements of the present embodiment similar or identical to that of above embodiments, similar or identical designations are used. Relevant descriptions of similar or identical elements which can be obtained with reference to above disclosure are not repeated here.

For example, after the three-dimensional structural view is created by the image detector, the adhesive dispensing or coating path can be set according to the three-dimensional structural view, such that the adhesive can be coated to the region 500P. As indicated in FIG. 4, the region 500P can surround three side surfaces of the entire display device module. In some embodiments, the region 500P can surround all side surfaces of the entire display device module, but the present disclosure is not limited thereto. Furthermore, the start position and the end position of the adhesive dispensing or coating path can be set according to the three-dimensional structural view. For example, the adhesive starts to be dispensed at the position S1, continues to be dispensed along the side surface of the assembled display device (comprising the display panel and the side surface of the device component) and ceases to be dispensed at the position S2. In some embodiments, the adhesive starts to be dispensed at the position S1, continues to be dispensed along the region 500P and ceases to be dispensed at the position S3, but the present disclosure is not limited thereto. In some embodiments, optical alignment and three-dimensional scan can be performed by the same image detector, but the present disclosure is not limited thereto.

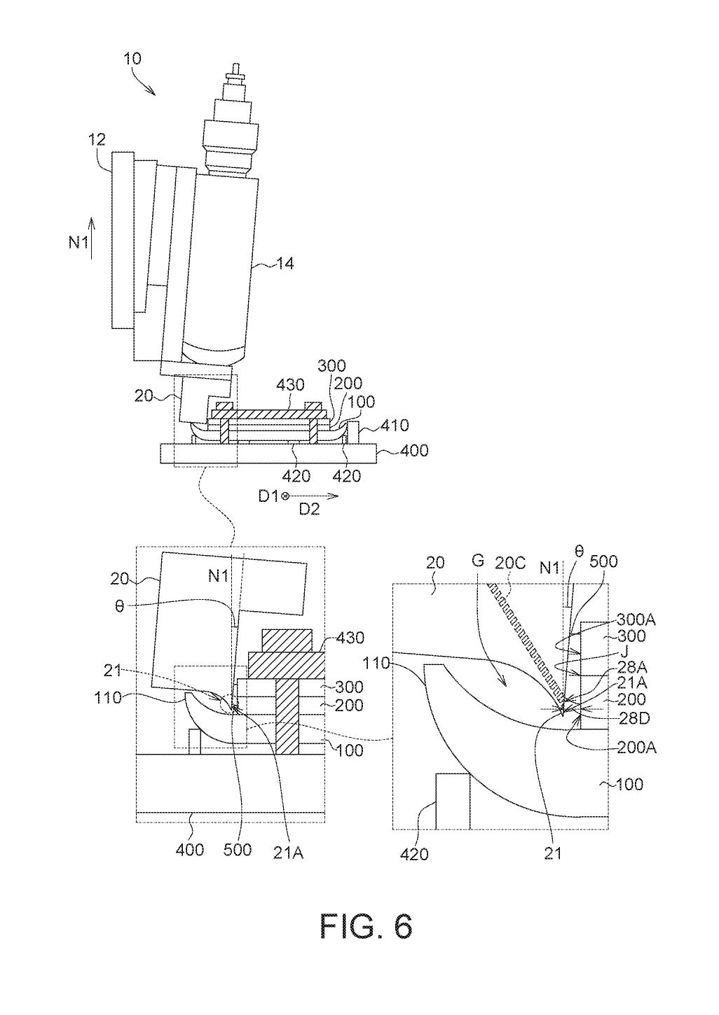

As indicated in FIG. 1 (also referring to FIG. 6), the dispensing extending portion 21 of the nozzle 20 of the dispensing device 10 extends to the gap G to dispense an adhesive to the side surface 200A and the component side surface 300A to form an adhesive layer 500. The extending portion surface 21A of the dispensing extending portion 21 has an opening (not illustrated FIG. 1), through which the dispensing device 10 dispenses the adhesive to the side surface 200A or the component side surface 300A to form the adhesive layer 500. In some embodiments, the extending portion surface 21A may have at least one opening, but the present disclosure is not limited thereto.

When the end portion 110 of the protection substrate 100 has a bending structure, the gap G formed among the end portion 110, the component side surface 300A and the side surface 200A becomes narrower. As disclosed in the embodiments of the present disclosure, the dispensing extending portion 21 can extend to the gap G to increase the flexibility and application scope of the dispensing device.

In some embodiments as indicated in FIG. 1, the gap width GW is ranged from 1 mm to 2 mm. In some embodiments, the gap width GW is ranged from 1.2 mm to 1.6 mm, but the present disclosure is not limited thereto. The gap width GW is defined as the minimal distance between the end portion 110 and the edge of the component side surface 300A farther away from the display panel 200. The gap depth GD is defined as the maximal distance of the gap in the normal direction of the first surface 200S1.

In an embodiment, the adhesive layer 500 is formed on the side surface 200A of the display panel 200 and the component side surface 300A of the device component 300. In some embodiments, under the circumstance that the function of the display device is not affected, a part of the adhesive layer 500 can be formed at the junction between the display panel 200 and the device component 300 to increase the viscosity between the display panel 200 and the device component 300. In some embodiments, the adhesive layer 500 can protect the side surface 200A of the display panel 200 or the component side surface 300A of the device component 300 and avoid the side surface 200A or the component side surface 300A being broken or indented when receiving an external force.

In some embodiments, the adhesive layer 500 can further be formed on the inner surface 100S of the protection substrate 100 to increase the viscosity between the protection substrate 100, the display panel 200 and the device component 300.

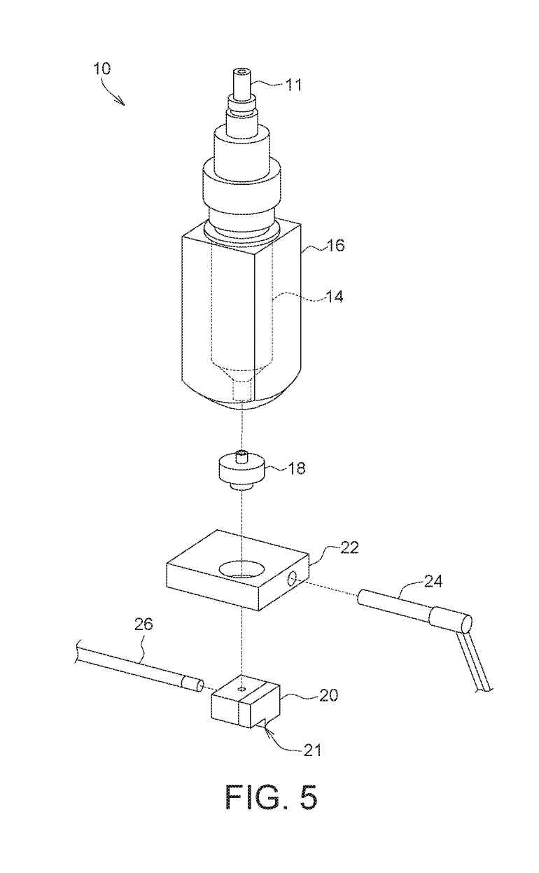

FIG. 5 is a three-dimensional structural view of a dispensing device according to an embodiment of the present disclosure. FIG. 6 is a side view of a dispensing device according to an embodiment of the present disclosure. For elements of the present embodiment similar or identical to that of above embodiments, similar or identical designations are used. Relevant descriptions of similar or identical elements which can be obtained with reference to above disclosure are not repeated here. In an embodiment as indicated in FIG. 6, the step of extending the dispensing extending portion 21 of the nozzle 20 of the dispensing device 10 to the gap G to dispense the adhesive further comprises: enabling the extending portion surface 21A of the dispensing extending portion 21 to tilt by an angle θ ranged from 0° to 80° with respect to the normal direction N1 of the platform 400. In some embodiments, the angle θ is ranged from 45° to 80°. In some embodiments, the angle θ is ranged from 10° to 45°. In some embodiments, the angle θ is ranged from 0° to 10°, but the present disclosure is not limited thereto. Detailed descriptions of tilting the extending portion surface 21A of the nozzle 20 of the dispensing device 10 by an angle with respect to the normal direction N1 of the platform 400 are disclosed below in the specification.

In some embodiments, the extending portion surface 21A faces the side surface 200A. In some embodiments, the extending portion surface 21A faces the component side surface 300A. In some embodiments, the extending portion surface 21A and the side surface 200A (or the component side surface 300A) are substantially parallel to each other. In some embodiments, the extending portion surface 21A and the side surface 200A can be separated by a distance at the part corresponding to the opening 28A. The distance can be defined as the shortest distance between the extending portion surface 21A and the side surface 200A at the part corresponding to the opening 28A. As indicated in FIG. 6, in some embodiments, the extending portion surface 21A and the side surface 200A are separated by a distance 28D ranged from 0.01 μm to 1 μm at the part corresponding to the opening 28A. In some embodiments, the distance 28D is ranged from 0.01 μm to 0.5 μm. In some embodiments, the extending portion surface 21A and the component side surface 300A are separated by a distance ranged from 0.01 μm to 1 μm at the part corresponding to the opening 28A. In some embodiments, the distance between the extending portion surface 21A and the component side surface 300A at the part corresponding to the opening 28A is ranged from 0.01 μm to 0.5 μm. If the distance between the extending portion surface 21A and the side surface 200A or the component side surface 300A is too small, the adhesive may not be successfully dispensed. If the distance between the extending portion surface 21A and the side surface 200A or the component side surface 300A is too large, the thickness of the adhesive layer 500 cannot be reduced or even the adhesive cannot be successfully coated on the side surface 200A or the component side surface 300A.

In some embodiments as indicated in FIG. 5 to FIG. 6, the dispensing device 10 may comprise a tilting mechanism 12. In an embodiment, the tilting mechanism 12 can modulate the tilting degree of the nozzle 20 according to the adhesive dispensing path and enable the extending portion surface 21A of the dispensing extending portion 21 to tilt by an angle θ with respect to the normal direction N1 of the platform 400. To put it in greater details, the dispensing device 10 may comprise an adhesive container 14 used for containing the adhesive. One end of the adhesive container 14 can be connected to the nozzle 20. The adhesive container 14 can also be connected to the tilting mechanism 12 through which the adhesive container 14 and the nozzle 20 tilt with respect to the platform 400, such that the extending portion surface 21A can tilt by an angle θ with respect to the normal direction N1 of the platform 400. In some embodiments, the dispensing device 10 can tilt the nozzle 20 by an angle using a mechanism or element other than the tilting mechanism 12 or using other method, but the present disclosure is not limited thereto.

In some embodiments, since the tilting mechanism 12 can move vertically in the normal direction N1 of the platform 400, the vertical path of the nozzle 20 in the normal direction N1 of the platform 400 can be set according to the three-dimensional structural view. Therefore, the adhesive dispensing or coating path of the nozzle 20 can be modulated according to the design of the dispensing extending portion 21 of the present disclosure (descriptions are disclosed below in the specification) or the tilting mechanism of the dispensing device 10. For example, by modulating the extending portion surface 21A of the nozzle 20 to tilt by an angle θ with respect to the normal direction N1 of the platform 400 or modulating the vertical movement of the nozzle 20, the adhesive can be more easily coated on the side surface of the display device whose structure has a special shape. For example, the present disclosure can be used in the manufacturing of the display device hose structure has a curved shape, a wavy shape, a rectangular shape, a polygonal shape, or a recessed shape, but the present disclosure is not limited thereto.

In some embodiments as indicated in FIG. 5 to FIG. 6, the dispensing device 10 may comprise an air valve connecting portion 11, a heating mechanism 16, a connecting mechanism 18, a heating base 22, a heater 24 or a sensor 26, but the present disclosure is not limited thereto. The heating mechanism 16 can surround the adhesive container 14. The adhesive container 14 and the nozzle 20 can be connected or detached through the connecting mechanism 18. The heating base 22 can surround the connecting mechanism 18. The heater 24 or the sensor 26 (can be realized by a temperature sensor) can be disposed adjacent to the heating base 22. The heater 24 can be used for heating the heating base 22. The sensor 26 can be used for sensing a temperature of the nozzle 20. The air valve connecting portion 11 can be connected to the air valve for providing an air pressure to push the adhesive off the adhesive container 14 to the nozzle 20. The elements, components, or mechanisms of the dispensing device 10 are exemplified above as an example of embodiment, but the present disclosure is not limited thereto.

In an embodiment, with the design of the heating mechanism 16 and the heating base 22, the adhesive can be heated when passing through the adhesive container 14 or the connecting mechanism 18, such that the adhesive can have better fluidity when being transported to the dispensing extending portion 21 via the channel 20C within the nozzle 20. In an embodiment, with the design of the connecting mechanism 18, the nozzle 20 can be easily detached or changed (for example, the nozzle can be changed to different sizes), such that the dispensing device 10 can be used for coating the adhesive to different display devices whose structures have special shapes.

In some embodiments, when the adhesive is dispensed to the side surface 200A or the component side surface 300A, the platform 400 is concurrently moved along a first direction D1 (referring to FIG. 4) substantially parallel to a lateral side of the display device. In some embodiments as indicated in FIG. 4 and FIG. 6, the first direction D1 can be the Y direction, and path parameters can be set according to the three-dimensional structural view, such that the platform 400 can move along the first direction D1. For example, the platform 400 can be moved to the position S2 from the position S1. In some embodiments, the platform 400 can be moved along a second direction D2 and then continues to be moved along a third direction D3. That is, through continuous or non-continuous movement, the platform 400 is moved to the position S2 from the position S1, and then is further moved to the position S3 from the position S2 and then stops, but the present disclosure is not limited thereto.

To summary, in some embodiments, the adhesive can be coated on the lateral sides of a display device module by fixing the position of the dispensing extending portion 21 and moving the platform 400. In some embodiments, the adhesive can be coated on the lateral sides of a display device by fixing the platform 400 and moving the position of the dispensing extending portion 21. However, the present embodiment is not subjected to specific restrictions regarding the said arrangement.

In some embodiment of the present disclosure, path parameters can be set according to the three-dimensional structural view, such that the nozzle can be horizontally moved in a direction parallel to the platform 400 (the X direction or the Y direction) or vertically moved in the normal direction N1 of the platform 400, or adjust the tilt angle θ between the extending portion surface 21A of the dispensing extending portion 21 and the normal direction N1. In some embodiments, the dispensing extending portion 21 can dispense the adhesive to the side surface 200A and the component side surface 300A along a path substantially following the junction J between the side surface 200A and the component side surface 300A. Through the above arrangement and operation, adhesive can be dispensed in a wide range of application, such as edge coating, curved surface coating, curve coating, slit coating or gap coating, but the present disclosure is not limited thereto.

The adhesive can be realized by a photo-curing adhesive, a moisture-curing adhesive, or a hot-melt adhesive. For example, the adhesive can be realized by a photo-curing adhesive (such as a black UV adhesive), an epoxy, an acrylic adhesive or a hot melt polyurethane (PUR) adhesive, other suitable adhesive, or a combination thereof, but the present disclosure is not limited thereto. In an embodiment, after the adhesive is dispensed to the side surface 200A or the component side surface 300A, the adhesive can be cured by a photo-curing method (using the UV light, but the present disclosure is not limited thereto) or a resting method (such as a moisture-curing method or a thermos-curing method) to form the adhesive layer 500, but the present disclosure is not limited thereto.

In some embodiments, after the adhesive is dispensed to the side surface 200A or the component side surface 300A to form an adhesive layer 500, a check step can be performed to check the adhesive layer 500. The check step comprises checking the thickness, the width, the uniformity or the appearance of the adhesive layer 500, but the present disclosure is not limited thereto. For example, optical scan can be performed to the entire structure of the protection substrate 100, the display panel 200 or the device component 300 or the adhesive layer 500, having been assembled together, by the image detector to confirm the coating position, thickness, width, uniformity or appearance of the adhesive layer 50. In some embodiments, optical alignment, three-dimensional scan or the check step can be performed using the same image sensing element, and the present disclosure is not limited thereto.

In some embodiments, the dispensing extending portion 21 can be realized by a slit nozzle or a needle nozzle, but the present disclosure is not limited thereto. As indicated in FIG. 5 to FIG. 6, the nozzle is a slit nozzle.

In some embodiments as indicated in FIG. 6, the dispensing extending portion 21 may further have an extending portion surface 21A disposed on the extending portion surface 21A. The extending portion surface 21A faces the side surface 200A or the component side surface 300A for dispensing an adhesive. After the adhesive is dispensed to the side surface 200A or the component side surface 300A from the opening 28A, through the contact between the extending portion surface 21A and the adhesive, the adhesive surface can be compressed or scratched as a flat adhesive state. Therefore, the adhesive layer 500 formed through the opening 28A combined with the contact dispensing of the extending portion surface 21A and the adhesive has a larger width or a smaller thickness, but the present disclosure is not limited thereto. A thinner adhesive layer 500 can be used in the lateral coating of narrow-border display device. A wider adhesive layer 500 can increase component viscosity of the display device.

For example, in some embodiments, the width of the adhesive layer 500 formed through the opening 28A combined with the contact dispensing of the extending portion surface 21A is ranged from 0.4 mm to 2 mm. In some embodiments, the width of the adhesive layer 500 is ranged from 0.5 mm to 1.5 mm, but the present disclosure is not limited thereto. The size of the opening 28A can be adjusted according to the width of the adhesive layer 500 to form different widths of the adhesive layer 500. The width of the adhesive layer 500 can be defined as the width of the adhesive layer 500 along the stacking direction of the display panel 200 and the device component 300, and detailed descriptions are disclosed below in the specification.

In some embodiments, the adhesive layer 500 has a thickness ranged from 0.05 mm to 0.2 mm. In some embodiment, the adhesive layer 500 has a thickness ranged from 0.05 mm to 0.15 mm, but the present disclosure is not limited thereto. The distance or the tilt angle between the extending portion surface 21A (comprising the opening 28A) and the display panel 200 or the device component 300 can be adjusted according to the thickness requirement of the adhesive layer 500 to achieve different thicknesses of the adhesive layer 500.

In some embodiments, the extending portion surface 21A is substantially parallel to the element surface (such as the side surface 200A and/or the component side surface 300A) of the adhesive layer 500, such that the flatness or uniformity of the adhesive layer 500 can be increased.

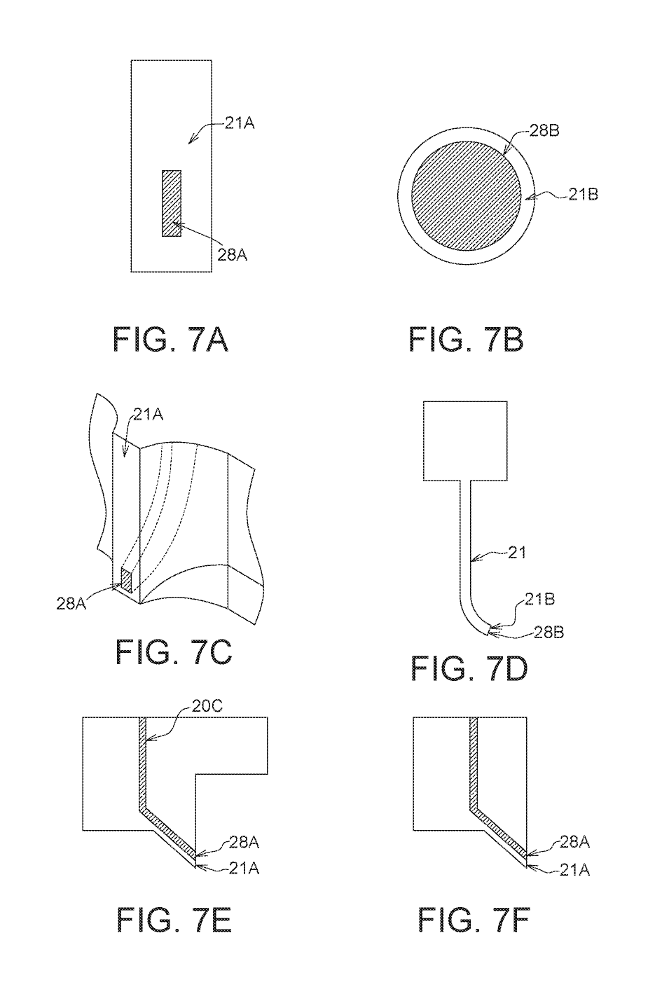

FIG. 7A to FIG. 7B are front views of a dispensing extending portion according to some embodiments of the present disclosure. FIG. 7C is a three-dimensional view of a dispensing extending portion according to an embodiment of the present disclosure. FIG. 7D to FIG. 7F are longitudinal sectional views of a dispensing extending portion according to some embodiments of the present disclosure. For elements of the present embodiment similar or identical to that of above embodiments, similar or identical designations are used. Relevant descriptions of similar or identical elements which can be obtained with reference to above disclosure are not repeated here.

The dispensing extending portion as indicated in FIG. 7A and FIG. 7C is a slit nozzle, and the extending portion surface 21A has an opening 28A for the slit nozzle. In an embodiment, the ratio of the area of the opening 28A to the area of the entire extending portion surface 21A (comprising opening 28A) is ranged from 3% to 40%. In other embodiments, the ratio of the area of the opening 28A to the area of the entire extending portion surface 21A (comprising opening 28A) is ranged from 5% to 20%, but the present disclosure is not limited thereto. In some embodiments, the opening 28A of the slit nozzle has a width ranged from 0.1 mm to 0.4 mm, the opening 28A has a length ranged from 1 mm to 2 mm. In some embodiments, the opening 28A of the slit nozzle has a width ranged from 0.2 mm to 0.3 mm, and the opening 28A has a length ranged from 0.5 mm to 1 mm, but the present disclosure is not limited thereto. The thickness and width of the adhesive layer may vary with the requirements of thickness and width of the adhesive layer. In the present disclosure, when the outline of the opening 28A has a rectangular, the length of the long side of the rectangle is defined as the length of the opening, and the width of the short side of the rectangle is defined as the width of the opening. In some embodiments, when the outline of the opening 28A is an oval shape, a circular shape, a triangular shape or a sharp-angled shape, the opening 28A may have multiple symmetric axes, the length of the longest symmetric axis of the opening is defined as the length of the opening, and the largest width perpendicular to the said longest symmetric axis and passing through the opening 28A is defined as the width of the opening. In some embodiments, when the opening 28A has an irregular shape, the long side and the short side of the smallest rectangle that can enclose the opening 28A are respectively defined as the length and the width of the opening.

The dispensing extending portion as indicated in FIG. 7B is a needle nozzle, and the extending portion surface 21B has an opening 28B. The opening 28B can have a circular shape, a rectangular shape, a polygonal shape or any other shape, but the present disclosure is not limited thereto. In some embodiments, the ratio of the area of the opening 28B of the dispensing extending portion of the needle nozzle to the area of the entire extending portion surface 21B (comprises the opening 28B) is ranged from 40% to 95%. In some embodiments, the area of the opening 28B of the dispensing extending portion of the needle nozzle to the extending portion surface 21B (comprises the opening 28B) is ranged from 70% to 80%, but the present disclosure is not limited thereto. In an embodiment, the length or width of the opening 28B of the needle nozzle can be larger than 0.5 mm, but the present disclosure is not limited thereto. The length or width of the opening 28B of the needle nozzle can be adjusted according to the size of the gap G of the coated elements.

The definition of the length or width of the opening 28B of the needle nozzle is the same as that of the opening 28A of the slit nozzle, and detailed descriptions are not repeated here.

The ratio of the area of the opening 28A of the slit nozzle to the area of the entire extending portion surface 21A (comprising opening 28A) is larger than the ratio of the area of the opening 28B of the needle nozzle to the area of the entire extending portion surface 21B (comprising opening 28B). Therefore, the extending portion surface having a larger ratio can benefit the thinness or uniformity of the adhesive layer 500.

As indicated in FIG. 7E to FIG. 7F being longitudinal sectional view of a slit nozzle, the opening 28A of the dispensing extending portion 21 is disposed at a terminal end of the dispensing extending portion 21, and the dispensing extending portion 21 has a narrower structure. As indicated in FIG. 7C, through the design of narrower structure, the dispensing extending portion 21 extends to the gap G, and the adhesive is transported to the opening 28A via the channel 20C to be dispensed to the side surface of the display device.

As indicated in FIG. 7D being a longitudinal sectional view of a needle nozzle, the dispensing extending portion 21 is a narrow tube, and the opening 28A is disposed at a terminal end of the dispensing extending portion 21, such that the dispensing extending portion 21 can extend to the gap G for dispensing the adhesive.

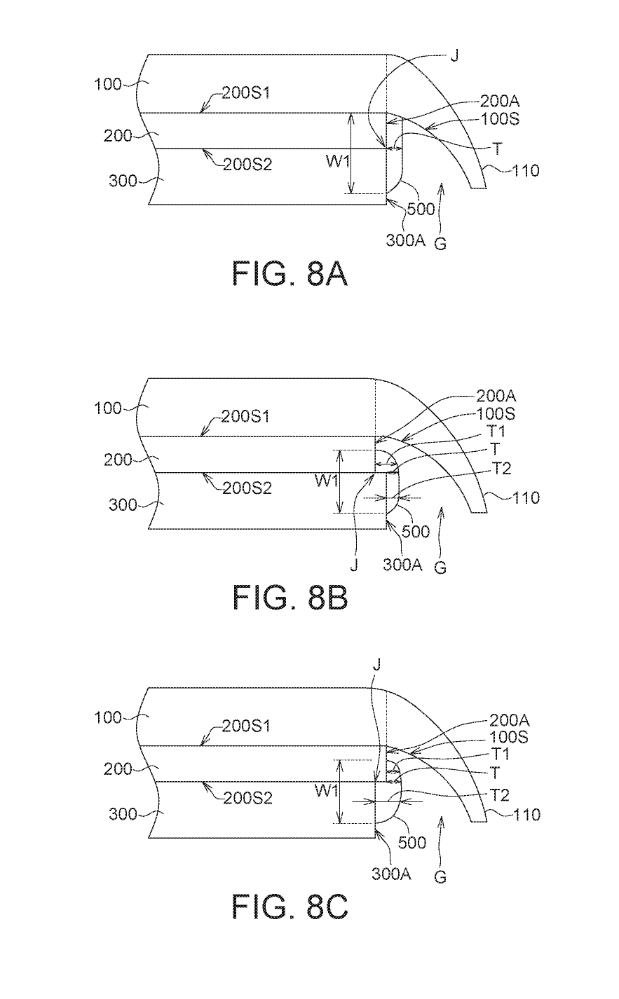

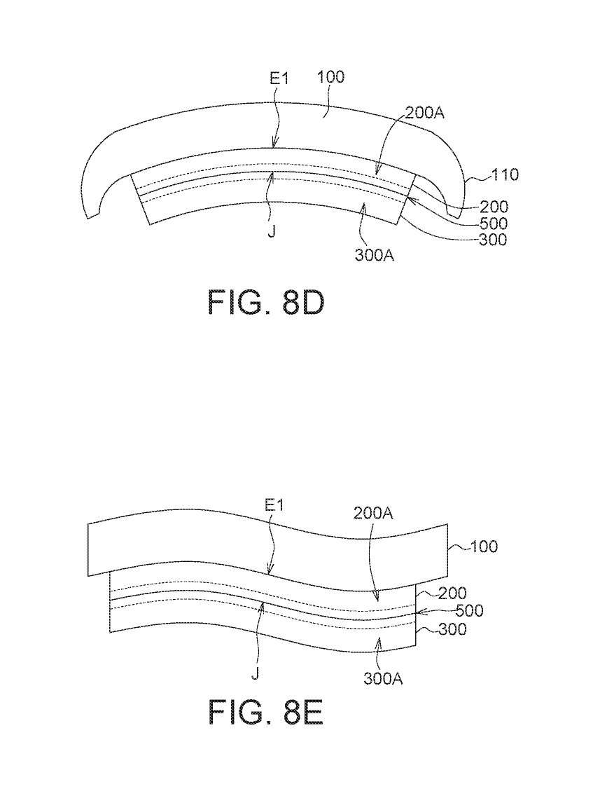

In some embodiment of the present disclosure, a display device is further provided. FIG. 8A to FIG. 8C are structural views of a side surface of a partial region of a display device according to some embodiments of the present disclosure. For elements of the present embodiment similar or identical to that of above embodiments, similar or identical designations are used. Relevant descriptions of similar or identical elements which can be obtained with reference to above disclosure are not repeated here.

In an embodiment as indicated in FIG. 8A, the display device comprises a display panel 200, a protection substrate 100, a device component 300 and an adhesive layer 500.

The display panel 200 has a first surface 200S1, a second surface 200S2 and a side surface 200A. The first surface 200S1 corresponds to the second surface 200S2. The side surface 200A connects the first surface 200S1 and the second surface 200S2. The protection substrate 100 and the display panel 200 are disposed oppositely. The protection substrate 100 has an inner surface 100S, disposed adjacent to the first surface 200S1 and the area of the inner surface 100S larger than the area of the first surface 200S1 of the display panel 200, and a end portion 110 extending towards the display panel 200. The device component 300 is disposed adjacent to the second surface 200S2. The display panel 200 is disposed between the device component 300 and the protection substrate 100. The device component 300 has a component side surface 300A. The adhesive layer 500 is disposed to the side surface 200A and the component side surface 300A.

In some embodiments, the adhesive layer 500 has a width W1 and a thickness T. In some embodiments, the ratio of the thickness T to the width W1 is ranged from 0.02 to 1.2. In some embodiments, the ratio of the thickness T to the width W1 is ranged from 0.025 to 0.6. In some embodiments as indicated in FIG. 8A, when the display panel 200 and the device component 300 have substantially the same projection areas on the first surface 200S1 (for example, the side surface 200A and the component side surface 300A substantially overlap in the normal direction of the first surface 200S1), the thickness T is the largest thickness of the adhesive layer 500 corresponding to the junction J between the display panel 200 and the device component 300.

In some embodiments as indicated in FIG. 8A, a part of the adhesive layer 500 is disposed on the end portion 110 of the protection substrate 100 (for example, the adhesive layer 500 is disposed on the inner surface 100S) to increase the conjugation grade between the protection substrate 100 and the display panel 200, but the present disclosure is not limited thereto.

In some embodiments, when the adhesive layer 500 is coated using a slit nozzle, the adhesive layer 500 has a width W1 ranged from 0.4 mm to 2 mm, and the adhesive layer 500 has a thickness ranged from 0.05 mm to 0.2 mm. In some embodiment, the adhesive layer 500 has a width W1 ranged from 0.5 mm to 1.5 mm, and the adhesive layer 500 has a thickness ranged from 0.1 mm to 0.15 mm, but the present disclosure is not limited thereto.

In some embodiments, when the adhesive layer 500 is coated using a needle nozzle, the adhesive layer 500 has a thickness ranged from 0.2 mm to 0.6 mm, and the adhesive layer 500 has a width W1 ranged from 0.5 to 1 mm. In some embodiment, when the adhesive layer 500 has a thickness ranged from 0.2 mm to 0.4 mm, the adhesive layer 500 has a width W1 ranged from 0.6 mm to 0.8 mm, but the present disclosure is not limited thereto.

In some embodiments, when the display panel 200 and the device component 300 have different projection areas on the first surface 200S1, or the side surface 200A and the component side surface 300A substantially do not overlap in the normal direction of the first surface 200S1, the adhesive layer 500 has a first thickness T1 and a second thickness T2. The first thickness T1 is the largest thickness of the adhesive layer 500 corresponding to the side surface 200A. The second thickness T2 is the largest thickness of the adhesive layer 500 corresponding to the component side surface 300A. The first thickness T1 is different from the second thickness T2. In the embodiment as indicated in FIG. 8B, when the projection area of the display panel 200 on the first surface 200S1 is smaller than the projection area of the device component 300 on the first surface 200S1, the side surface 200A is indented more inwardly than the component side surface 300A. Meanwhile, the thickness T is still the largest thickness of the adhesive layer 500 corresponding to the junction J between the side surface 200A of the display panel 200 and component side surface 300A of the device component 300, the first thickness T1 of the adhesive layer 500 is larger than the second thickness T2, and the second thickness T2 is substantially equivalent to the thickness T.

In an embodiment as indicated in FIG. 8C, when the projection area of the display panel 200 on the first surface 200S1 is larger than the projection area of the device component 300 on the first surface 200S1, the side surface 200A is protruded more outwardly than the component side surface 300A. Meanwhile, the thickness T is still the largest thickness of the adhesive layer 500 corresponding to the junction J between the side surface 200A of the display panel 200 and the component side surface 300A of the device component 300, the first thickness T1 of the adhesive layer 500 is smaller than the second thickness T2, and the first thickness T1 is substantially equivalent to the thickness T.

Referring to FIG. 8D to FIG. 8E, structural views of a side surface of a display device according to some embodiments of the present disclosure are shown. As indicated in FIG. 8D to FIG. 8E, the first bending edge E1 of the side surface of the display panel 200 has an arced shape, and the first bending edge E1 of the side surface of FIG. 8E the display panel 200 has a wavy shape. In some embodiments, the first bending edge E1 can have other shapes, but the present disclosure is not limited thereto. The junction J between the side surface 200A of the display panel 200 and the component side surface 300A of the device component 300 substantially corresponds to the arced shape or the wavy shape of the first bending edge E1. Therefore, the adhesive layer 500 can be disposed on the side surface 200A and the component side surface 300A along the junction J, but the present disclosure is not limited thereto.

In an embodiment, the first bending edge E1 of FIG. 6 and FIG. 8D to FIG. 8E is the bending edge of the side surface of the display panel 200 along the first direction D1 of FIG. 6. In some other embodiments, the side surface of the display panel 200 has a second bending edge, such as the bending edge of the side surface of the display panel 200 along the second direction D2. As disclosed above, the junction J between the display panel 200 and the device component 300 substantially corresponds to the outline of the second bending edge. Therefore, the adhesive layer 500 can be disposed to the side surface 200A and the component side surface 300A along the junction J.

While the disclosure has been described by way of example and in terms of the embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A manufacturing method of a display device, comprising:
assembling a protection substrate and a display panel, wherein the protection substrate has an inner surface, facing a first surface of the display panel, an area of the inner surface of the protection substrate is larger than an area of the first surface of the display panel, and an end portion extends towards the display panel;
assembling a device component and the display panel disposed between the device component and the protection substrate, wherein the device component has a component side surface, the display panel has a side surface, and a gap is formed among the end portion, the component side surface of the device component and the side surface of the display panel;
extending a dispensing extending portion to the gap; and
dispensing an adhesive to the side surface of the device component and the component side surface of the device component to form an adhesive layer.

2. The manufacturing method of the display device according to claim 1, wherein following the step of assembling the protection substrate and the display panel, the manufacturing method further comprises:
placing the protection substrate on a platform.

3. The manufacturing method of the display device according to claim 2, wherein the step of extending the dispensing extending portion to the gap further comprises tilting an extending portion surface of the dispensing extending portion by an angle from 0 to 80° with respect to a normal direction of the platform, and the extending portion surface of the dispensing extending portion has an opening and faces the side surface of the display panel.

4. The manufacturing method of the display device according to claim 1, wherein the step of dispensing the adhesive to the side surface of the display panel and the component side surface of the device component comprises:
enabling the dispensing extending portion to dispense the adhesive to the side surface of the display panel and the component side surface of the device component along a path corresponding to a junction between the side surface of the display panel and the component side surface of the device component.

5. The manufacturing method of the display device according to claim 3, wherein in the step of extending the dispensing extending portion to the gap, the extending portion surface and the side surface of the device component are separated by a distance from 0.01 μm to 0.5 μm.

6. The manufacturing method of the display device according to claim 1, wherein the step of dispensing the adhesive to the side surface of the device component and the component side surface of the device component comprises:
curing the adhesive by a photo-curing method or a resting method.

7. The manufacturing method of the display device according to claim 1, wherein following the step of dispensing the adhesive, the manufacturing method further comprises checking the adhesive layer.

8. A display device, comprising:
a display panel having a first surface, a second surface and a side surface, wherein the first surface corresponds to the second surface, and the side surface connects the first surface and the second surface;
a protection substrate disposed opposite to the display panel, wherein the protection substrate has an inner surface adjacent to the first surface of the display panel, an area of the inner surface of the protection substrate is larger than an area of the first surface of the display panel, and an end portion extends towards the display panel;
a device component disposed adjacent to the second surface of the display panel and having a component side surface; and
an adhesive layer disposed on the side surface of the display panel and the component side surface of the device component.

9. The display device according to claim 8, wherein the adhesive layer has a thickness ranged from 0.05 mm to 0.6 mm.

10. The display device according to claim 8, wherein the adhesive layer has a width and a thickness, and a ratio of the thickness to the width is ranged from 0.02 to 1.2.

11. The display device according to claim 10, wherein the adhesive layer further comprises a first thickness and a second thickness, and the first thickness is different from the second thickness.

12. The display device according to claim 11, wherein the first thickness is the largest thickness of the adhesive layer corresponding to the side surface of the display panel.

13. The display device according to claim 11, wherein the second thickness is the largest thickness of the adhesive layer 500 corresponding to the component side surface of the device component.

14. The display device according to claim 11, wherein the first thickness is larger than the second thickness,

15. The display device according to claim 9, wherein the thickness is the largest thickness of the adhesive layer corresponding to a junction between the side surface of the display panel and the component side surface of the device component.

16. The display device according to claim 8, wherein the side surface of the display panel is protruded more outwardly than the component side surface of the device component when a projection area of the display panel on the first surface is larger than a projection area of the device component 300 on the first surface.

17. The display device according to claim 8, wherein the side surface of the display panel comprises a first bending edge.

18. The display device according to claim 17, wherein the first bending edge of the side surface of the display panel has an arced shape.

19. The display device according to claim 17, wherein the first bending edge of the side surface of the display panel has a wavy shape.

20. The display device according to claim 15, wherein the adhesive layer is disposed on the side surface of the display panel and the component side surface of the device component along the junction.
